(19) United States
(12) Patent Application Publication
(10) Pub. No.: US 2025/0362611 A1
(43) Pub. Date: Nov. 27, 2025

(54) RESIST UNDERLAYER COMPOSITIONS AND METHODS OF FORMING PATTERNS USING THE COMPOSITIONS

(71) Applicant: SAMSUNG SDI CO., LTD., Yongin-si (KR)

(72) Inventors: Seongjin KIM, Suwon-si (KR); Jungin MUN, Suwon-si (KR); Changmo LIM, Suwon-si (KR); Byeong Gyu HWANG, Suwon-si (KR); Hwayoung JIN, Suwon-si (KR); Soojeung KIM, Suwon-si (KR); Eunsu LEE, Suwon-si (KR); Jihye LEE, Suwon-si (KR); Jaemin LEE, Suwon-si (KR); Junyoung JANG, Suwon-si (KR); Ahra CHO, Suwon-si (KR); Yoojeong CHOI, Suwon-si (KR); Sungwoo JUNG, Suwon-si (KR)

(21) Appl. No.: 19/215,043

(22) Filed: May 21, 2025

(30) Foreign Application Priority Data
May 23, 2024 (KR) 10-2024-0067377

(51) Int. Cl. G03F 7/11; G03F 7/36

(52) U.S. Cl. CPC G03F 7/11; G03F 7/36

(57) ABSTRACT

Disclosed are a resist underlayer composition, and a method of forming a photoresist pattern using the resist underlayer composition. The resist underlayer composition includes a polymer including a structural unit represented by Chemical Formula 1, and a solvent. The definition of Chemical Formula 1 is as described in the specification.

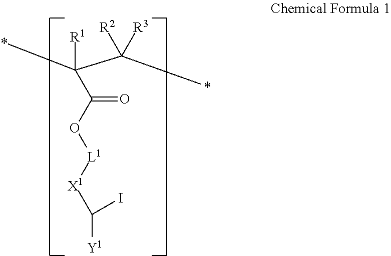

### CROSS-REFERENCE TO RELATED APPLICATION

The present application claims priority to and the benefit of Korean Patent Application No. 10-2024-0067377, filed on May 23, 2024, in the Korean Intellectual Property Office, the entire content of which is hereby incorporated by reference.

### BACKGROUND

### 1. Field

Embodiments of this disclosure relate to resist underlayer compositions, and methods of forming patterns using the same.

### 2. Description of the Related Art

Recently, the semiconductor industry has developed to an ultra-fine technique having a pattern of several to several tens of nanometer size. Such ultrafine technique essentially needs effective lithographic techniques.

A lithographic technique is a processing method that includes coating a photoresist film on a semiconductor substrate such as a silicon wafer to form a thin film, irradiating the photoresist film with activating radiation such as ultraviolet rays through a mask pattern on which the device pattern is drawn of formed, developing the resultant to obtain a photoresist pattern, and etching the substrate using the photoresist pattern as a protective layer to form a fine pattern corresponding to the pattern, on the surface of the substrate.

As semiconductor patterns become increasingly finer, a thickness of the photoresist layer should be thin, and accordingly, a thickness of the resist underlayer also should be thin. The resist underlayer should not collapse the photoresist pattern even if it is thin, should have good adhesion to the photoresist, and should be formed to have a uniform (or substantially uniform) thickness. The resist underlayer should have a high refractive index and low extinction coefficient for the light used in photolithography and a faster etch rate than the photoresist layer.

### SUMMARY

The resist underlayer composition according to some example embodiments of the present disclosure improves patterning performance and energy efficiency by improving sensitivity to an exposure light source even in a fine patterning process, and provides a resist underlayer having a uniform (or substantially uniform) pattern.

Some example embodiments provide a method of forming a pattern using the resist underlayer composition.

A resist underlayer composition according to some example embodiments includes a polymer including a structural unit represented by Chemical Formula 1, and a solvent:

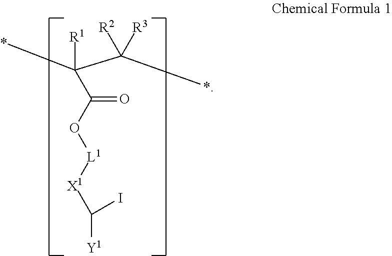

In Chemical Formula 1,

R¹ to R³ are each independently hydrogen, deuterium, or a substituted or unsubstituted C1 to C10 alkyl group,

L¹ is a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C1 to C10 heteroalkylene group, a substituted or unsubstituted C2 to C10 heteroalkenylene group, or a combination thereof,

X¹ is a single bond (e.g., a single covalent bond), —O—, —C(═O)—, —(CO)O—, —O(CO)O—, —NR^{a}— (wherein, R^{a} is hydrogen, deuterium, or a substituted or unsubstituted C1 to C10 alkyl group), or a combination thereof,

Y¹ is *—(CH₂)n-(CHI)m-CR^{x}R^{y}R^{z} (wherein, n is one of the integers from 0 to 5, m is 0 or 1, and R^{x} to R^{z} are each independently hydrogen, deuterium, or a halogen atom), a substituted or unsubstituted C3 to C20 cycloalkyl group, two or more fused rings of substituted or unsubstituted C3 to C10 cycloalkyl groups, a substituted or unsubstituted C2 to C20 heterocycloalkyl group, a substituted or unsubstituted C6 to C20 aryl group, or a substituted or unsubstituted C2 to C20 heteroaryl group, and

* is a linking point.

In Chemical Formula 1, L¹ may be a substituted or unsubstituted C1 to C10 alkylene group, and X¹ may be —(CO)O—.

The polymer may include a structural unit represented by Chemical Formula 1-1:

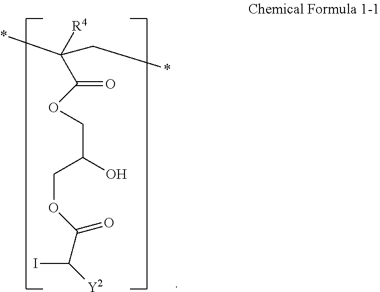

In Chemical Formula 1-1,

R⁴ is hydrogen, deuterium, or a substituted or unsubstituted C1 to C10 alkyl group,

Y² is a substituted or unsubstituted methyl group, —CHICH₃, a substituted or unsubstituted C3 to C20 cycloalkyl group, two or more fused rings of substituted or unsubstituted C3 to C10 cycloalkyl groups, or a substituted or unsubstituted C6 to C10 aryl group, and
* is a linking point.

The polymer may further include a structural unit represented by Chemical Formula 2:

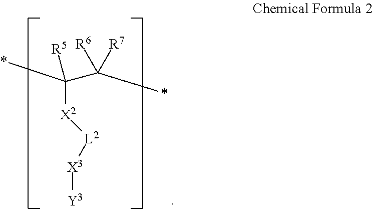

In Chemical Formula 2,

R⁵ to R⁷ are each independently hydrogen, deuterium, or a substituted or unsubstituted C1 to C10 alkyl group,

X² and X³ are each independently a single bond (e.g., a single covalent bond), —O—, —S—, —S(═O)—, —S(═O)₂—, —C(═O)—, —(CO)O—, —O(CO)O—, —NR^{b}— (wherein, R^{b} is hydrogen, deuterium, or a C1 to C10 alkyl group), or a combination thereof,

L² is a single bond (e.g., a single covalent bond), a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C2 to C20 heteroarylene group, or a combination thereof,

Y³ is hydrogen, deuterium, a hydroxy group, a nitro group, a cyano group, amine group, —COOH, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, or a substituted or unsubstituted C2 to C20 heteroaryl group, and

* is a linking point.

In Chemical Formula 2, X² may be —(CO)O—, X³ may be a single bond (e.g., a single covalent bond), and Y³ may be a substituted or unsubstituted C1 to C10 alkyl group, a substituted or unsubstituted C3 to C20 cycloalkyl group, or a substituted or unsubstituted C6 to C20 aryl group.

The polymer may include one or more selected from among the structural units represented by Chemical Formula 1-2 to Chemical Formula 1-5:

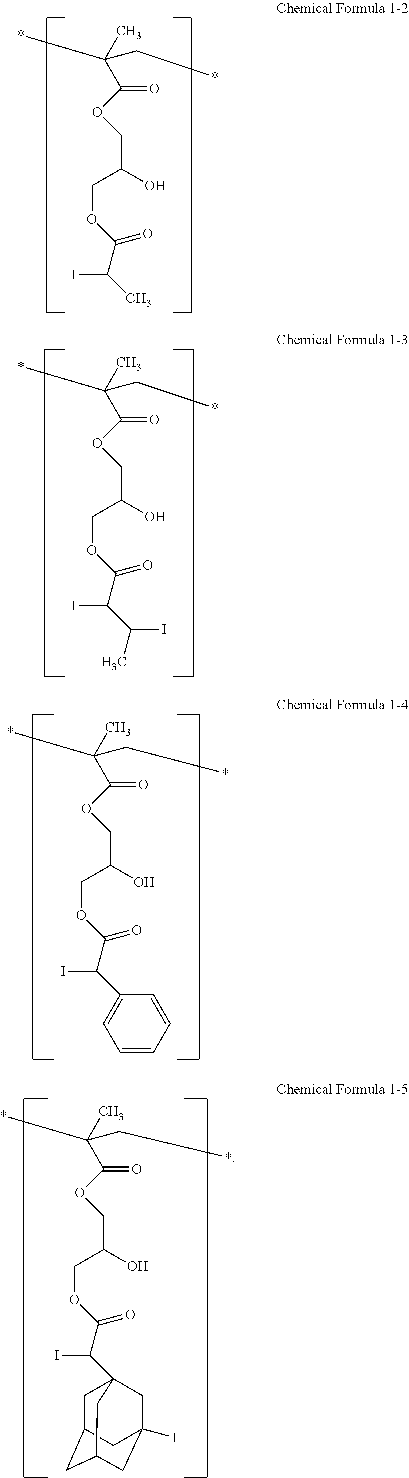

An amount of the structural unit represented by Chemical Formula 1 may be about 20 wt % to about 80 wt % based on a total weight of the polymer.

A weight average molecular weight (Mw) of the polymer may be about 1,000 grams per mole (g/mol) to about 300,000 g/mol.

The polymer may be included in an amount of about 0.1 wt % to about 50 wt % based on a total weight of the resist underlayer composition.

The composition may further include one or more polymers selected from among an acrylic resin, an epoxy resin, a novolac-based resin, a glycoluril-based resin, and a melamine-based resin.

The composition may further include an additive including a surfactant, a thermal acid generator, a photoacid generator, a plasticizer, or a combination thereof.

According to some example embodiments, a method of forming a pattern includes forming an etching target layer on a substrate, forming a resist underlayer by applying the resist underlayer composition according to some example embodiments, forming a photoresist pattern on the resist underlayer, and sequentially etching the resist underlayer and the etching target layer using the photoresist pattern as an etching mask.

The resist underlayer composition according to some example embodiments can improve storage stability and patterning performance and energy efficiency by improving sensitivity to an exposure light source even in a fine patterning process, and at the same time provide a resist underlayer in which a pattern is formed uniformly (or substantially uniformly).

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-6 are cross-sectional views illustrating a method of forming a pattern using a resist underlayer composition according to some example embodiments.

### DETAILED DESCRIPTION

Example embodiments of the present disclosure will hereinafter be described in more detail, and may be easily practiced by a person having ordinary skill in the art. However, the subject matter of this disclosure may be embodied in many different forms and is not construed as limited to the example embodiments set forth herein.

In the drawings, the thickness of layers, films, panels, regions, etc., may be exaggerated for clarity and like reference numerals designate like elements throughout the specification. It will be understood that if (e.g., when) an element such as a layer, film, region, or substrate is referred to as being “on” another element, it can be directly on the other element or intervening elements may also be present. In embodiments, if (e.g., when) an element is referred to as being “directly on” another element, there are no intervening elements present.

As used herein, if (e.g., when) a definition is not otherwise provided, “substituted” refers to replacement of a hydrogen atom of a compound by a substituent selected from deuterium, a halogen (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and a combination thereof.

In embodiments, two adjacent substituents of the substituted halogen atom (F, Br, Cl, or I), hydroxy group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused with each other to form a ring.

As used herein, “heterocyclic group” includes a heteroaryl group, and a cyclic group including at least one heteroatom selected from N, O, S, P, and Si instead of carbon (C) of a cyclic compound such as an aryl group, a cycloalkyl group, a fused ring thereof, or a combination thereof. If (e.g., when) the heterocyclic group is a fused ring, each or entire ring of the heterocyclic group may include at least one heteroatom.

In embodiments, a substituted or unsubstituted aryl group and/or a substituted or unsubstituted heterocyclic group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiphenyl group, a substituted or unsubstituted carbazolyl group, pyridoindolyl group, a benzopyridooxazinyl group, a benzopyridothiazinyl group, a 9,9-dimethyl-9,10-dihydroacridinyl group, a combination thereof, or a combined fused ring of the foregoing groups, but are not limited thereto.

As used herein, if (e.g., when) specific definition is not otherwise provided, the term “combination” refers to mixing or copolymerization.

In embodiments, as used herein, the term “polymer” may include both oligomers and polymers.

Unless otherwise specified in the present specification, the weight average molecular weight may be measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In embodiments, unless otherwise defined in the specification, “*” indicates a linking point of a structural unit or a moiety of a polymer.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, and/or the like may be used herein to describe certain elements, these elements should not be limited by these terms. These terms are only used to distinguish one element from another element. Thus, a first element could be termed a second element without departing from the teachings of the present disclosure. Similarly, a second element could be termed a first element.

As used herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, alternative language such as “or” is not to be construed as an exclusive meaning, for example, “A or B” is construed to include A, B, A+B, and/or the like. Similarly, the term “and/or” includes any and all combinations of one or more of the associated listed items. The symbol “/” used herein may be interpreted as “and” or as “or” according to the context.

As used herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added. The term “combination thereof” may include a mixture, a laminate, a complex, a copolymer, an alloy, a blend, a reactant of constituents.

As used herein, singular forms such as “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element. Similarly, alternative language such as “or” refers to “one or more” or “some” “embodiments of the present disclosure,” each including a corresponding listed item.

In this context, “consisting essentially of” means that any additional components will not materially affect the chemical, physical, optical or electrical properties of the semiconductor film.

In the semiconductor industry, there is a constant desire or demand to reduce the size of semiconductor chips (e.g., including an integrated circuit). In order to meet this trend, a line width of the resist pattern (e.g., photoresist pattern) used in lithography technology should be reduced to a level of (e.g., at most) several tens of nanometers, and the pattern (e.g., photoresist pattern) formed in this way is used to transfer a pattern (e.g., template circuit pattern) to a lower material (e.g., a material under the pattern) by using an etching process on a lower substrate (e.g., a substrate under the pattern). However, as the pattern size of the resist (e.g., photoresist pattern) becomes smaller, a height (aspect ratio) of the resist (e.g., photoresist pattern) that can withstand or accommodate the line width is limited, and accordingly, the resist (e.g., photoresist pattern) may not have suitable or sufficient resistance in the etching step. Therefore, a resist underlayer has been used to compensate for this if (e.g., when) a thin resist material is used, if (e.g., when) the substrate to be etched is thick, or if (e.g., when) a deep pattern is required or desired.

The resist underlayer should become thinner as the thickness of the resist becomes thinner, and the photoresist pattern should not collapse even if the resist underlayer is thin. For this purpose, the resist underlayer should have excellent adhesion to the photoresist. In embodiments, in forming a thin resist underlayer, coating uniformity of the resist underlayer composition and flatness of the resist underlayer produced therefrom should be improved or enhanced, and sensitivity to the exposure light source should be improved or enhanced to improve or enhance pattern (e.g., photoresist pattern) formability and energy efficiency.

A resist underlayer composition according to some example embodiments includes a polymer including a structural unit represented by represented by Chemical Formula 1, and a solvent:

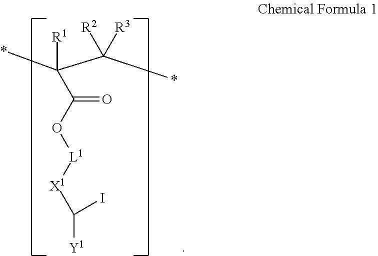

In Chemical Formula 1,

R¹ to R³ each independently be hydrogen, deuterium, or a substituted or unsubstituted C1 to C10 alkyl group,

L¹ may be a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C1 to C10 heteroalkylene group, a substituted or unsubstituted C2 to C10 heteroalkenylene group, or a combination thereof,

X¹ may be a single bond (e.g., a single covalent bond), —O—, —C(═O)—, —(CO)O—, —O(CO)O—, —NR^{a}— (wherein, R^{a} may be hydrogen, deuterium, or a substituted or unsubstituted C1 to C10 alkyl group), or a combination thereof,

Y¹ may be *—(CH₂)n-(CHI)m-CR^{x}R^{y}R^{z} (wherein, n may be one of the integers from 0 to 5, m is 0 or 1, and R^{x} to R^{z} may each independently be hydrogen, deuterium, or a halogen atom), a substituted or unsubstituted C3 to C20 cycloalkyl group, two or more fused rings of substituted or unsubstituted C3 to C10 cycloalkyl groups, a substituted or unsubstituted C2 to C20 heterocycloalkyl group, a substituted or unsubstituted C6 to C20 aryl group, or a substituted or unsubstituted C2 to C20 heteroaryl group, and

* is a linking point.

In the resist underlayer composition according to some example embodiments, because the polymer includes iodine, the absorption rate of the exposure light source is high during exposure, thereby inducing the generation of secondary electrons in the photoresist of the resist underlayer upper (e.g., an upper surface of the resist underlayer), and also improving sensitivity of the photoresist.

For example, in the structural unit represented by Chemical Formula 1 of the polymer, the carbon atom bound to the terminal functional group Y¹ may be substituted with iodine, enabling maximum absorption (or substantially increased absorption) of light from the light source by the resist underlayer composition and maximizing (or substantially increasing) sensitivity of the photoresist.

In some example embodiments, R¹ to R³ may each independently be hydrogen, deuterium, or a substituted or unsubstituted C1 to C10 alkyl group, for example, hydrogen, a methyl group, or an ethyl group, but are not limited thereto.

In some example embodiments, L¹ may be a single bond (e.g., a single covalent bond), a substituted or unsubstituted C1 to C10 alkylene group, a substituted or unsubstituted C2 to C10 alkenylene group, a substituted or unsubstituted C2 to C10 alkynylene group, a substituted or unsubstituted C1 to C10 heteroalkylene group., or a combination thereof, for example, a single bond (e.g., a single covalent bond), a substituted or unsubstituted C1 to C10 alkylene group, a substituted or unsubstituted C2 to C10 alkenylene group, or a combination thereof, for example, a single bond (e.g., a single covalent bond), or a substituted or unsubstituted C1 to C5 alkylene group, for example, a C1 to C5 alkylene group substituted with a hydroxy group, for example, a propylene group substituted with a hydroxy group, but is not limited thereto.

In some example embodiments, X¹ may be a single bond (e.g., a single covalent bond), —O—, —C(═O)—, —(CO)O—, —O(CO)O—, —NH—, —N(CH₃)—, or a combination thereof, for example, —(CO)O—, or —NH—, or, for example, —(CO)O—, but is not limited thereto.

In some example embodiments, Y¹ may be *—(CH₂)n-(CHI)m-CR^{x}R^{y}R^{z} (wherein, n may be one of the integers from 0 to 5, m is 0 or 1, and R^{x} to R^{z} may each independently be hydrogen, deuterium, or a halogen atom), a substituted or unsubstituted C3 to C10 cycloalkyl group, two or more fused rings of substituted or unsubstituted C3 to C10 cycloalkyl groups, a substituted or unsubstituted C2 to C10 heterocycloalkyl group, a substituted or unsubstituted C6 to C14 aryl group, or a substituted or unsubstituted C2 to C20 heteroaryl group, for example, *—(CH₂)n-(CHI)m-CH₃ (wherein, n may be one of integers of 0 to 2 and m is 0 or 1), two or more fused rings of substituted or unsubstituted C3 to C10 cycloalkyl groups, or a substituted or unsubstituted C6 to C10 aryl group, but is not limited thereto.

In some example embodiments, Chemical Formula 1 may include a structural unit represented by Chemical Formula 1-1:

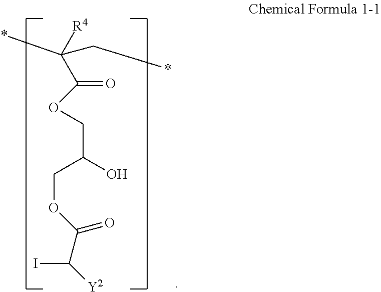

In Chemical Formula 1-1, R⁴ may be hydrogen, deuterium, or a substituted or unsubstituted C1 to C10 alkyl group, Y² may be a substituted or unsubstituted methyl group, —CHICH₃, a substituted or unsubstituted C3 to C20 cycloalkyl group, two or more fused rings of substituted or unsubstituted C3 to C10 cycloalkyl groups, or a substituted or unsubstituted C6 to C10 aryl group, and * is a linking point.

In some example embodiments, Y² may be a substituted or unsubstituted methyl group, —CHICH₃, a substituted or unsubstituted C3 to C10 cycloalkyl group, two or more fused rings of substituted or unsubstituted C3 to C10 cycloalkyl groups, or a substituted or unsubstituted C6 to C10 aryl group, but is not limited thereto.

As an example, two or more fused rings of the substituted or unsubstituted C3 to C10 cycloalkyl group of Y² may be formed by fusing two, three, or four substituted or unsubstituted C3 to C10 cycloalkyl groups, for example, a fused ring formed if (e.g., when) two cyclohexanes share 2 or 3 carbon atoms with another cyclohexane, a fused ring formed if (e.g., when) three cyclohexanes each share carbon atoms with different cyclohexane, or a fused ring formed if (e.g., when) 4 cyclohexanes each share carbon atoms with different cyclohexane, but are not limited to thereto. As an example, any one or more selected from among the hydrogens in the fused ring may be substituted with another group, for example, iodine, but are not limited thereto.

As an example, the polymer may include one or more selected from among the structural units represented by Chemical Formula 1-2 to Chemical Formula 1-5:

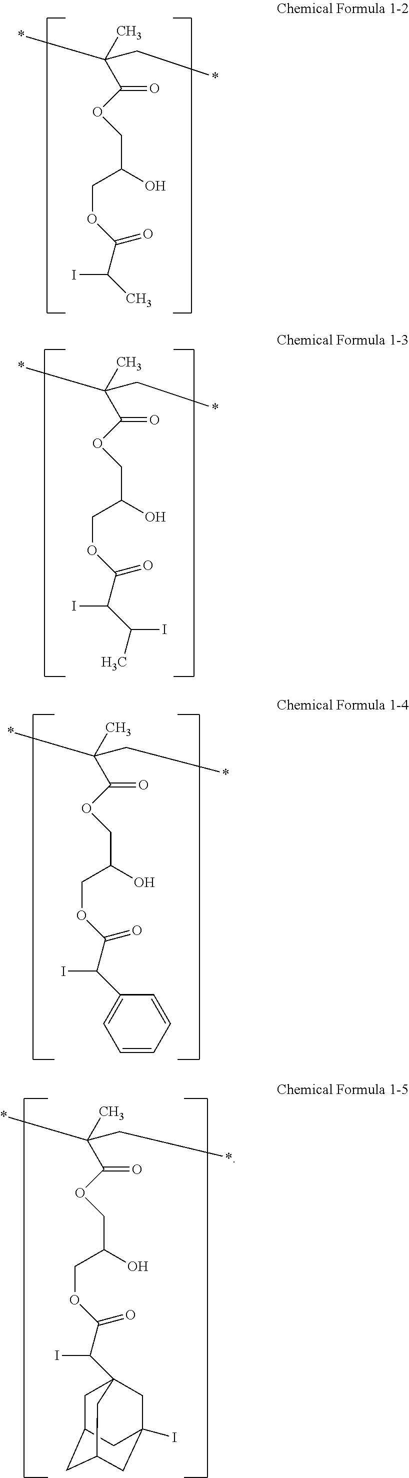

The polymer included in the resist underlayer composition according to some example embodiments may further include a structural unit represented by Chemical Formula 2:

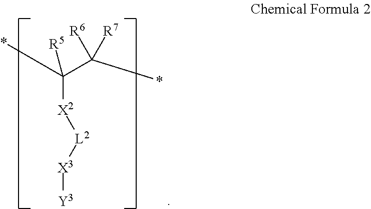

In Chemical Formula 2,

R⁵ to R⁷ may each independently be hydrogen, deuterium, or a substituted or unsubstituted C1 to C10 alkyl group,

X² and X³ may each independently be a single bond (e.g., a single covalent bond), —O—, —S—, —S(═O)—, —S(═O)₂—, —C(═O)—, —(CO)O—, —O(CO)O—, —NR^{b}— (wherein, R^{b} may be hydrogen, deuterium, or a C1 to C10 alkyl group), or a combination thereof,

L² may be a single bond (e.g., a single covalent bond), a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C2 to C20 heteroarylene group, or a combination thereof,

Y³ may be hydrogen, deuterium, a hydroxy group, a nitro group, a cyano group, amine group, —COOH, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, or a substituted or unsubstituted C2 to C20 heteroaryl group, and

* is a linking point.

In some example embodiments, R⁵ to R⁷ may each independently be hydrogen, deuterium, or a substituted or unsubstituted C1 to C5 alkyl group, for example, hydrogen, or a methyl group, but are not limited thereto.

In some example embodiments, X² and X³ may each independently be a single bond (e.g., a single covalent bond), —O—, —S—, —S(═O)—, —S(═O)₂—, —C(═O)—, —(CO)O—, —O(CO)O—, —NH—, or a combination thereof, for example, a single bond (e.g., a single covalent bond), —O—, —C(═O)—, —(CO)O—, —O(CO)O—, —NH—, or a combination thereof, for example, a single bond (e.g., a single covalent bond), or —(CO)O—, but are not limited thereto.

In some example embodiments, L² may be a single bond (e.g., a single covalent bond), a substituted or unsubstituted C1 to C10 alkylene group, a substituted or unsubstituted C1 to C10 heteroalkylene group, or a combination thereof, for example, a single bond (e.g., a single covalent bond), or a substituted or unsubstituted C1 to C10 alkylene group, for example, a single bond (e.g., a single covalent bond), or a substituted or unsubstituted C1 to C5 alkylene group, but is not limited thereto.

In some example embodiments, Y³ may be hydrogen, deuterium, a hydroxy group, a nitro group, a cyano group, amine group, —COOH, a substituted or unsubstituted C1 to C10 alkyl group, a substituted or unsubstituted C2 to C10 alkenyl group, a substituted or unsubstituted C1 to C10 heteroalkyl group, a substituted or unsubstituted C2 to C10 heteroalkenyl group, a substituted or unsubstituted C3 to C20 cycloalkyl group, a substituted or unsubstituted C2 to C20 heterocycloalkyl group, or a substituted or unsubstituted C6 to C20 aryl group, for example, a substituted or unsubstituted C1 to C10 alkyl group, a substituted or unsubstituted C3 to C20 cycloalkyl group, or a substituted or unsubstituted C6 to C20 aryl group, for example, a substituted or unsubstituted C1 to C5 alkyl group, or a substituted or unsubstituted C3 to C10 cycloalkyl group, but is not limited thereto.

The structural unit represented by Chemical Formula 1 may be included in an amount of about 20 wt % to about 80 wt % based on a total weight of the polymer. In embodiments, the structural unit represented by Chemical Formula 1 may be included in an amount of about 20 wt % to about 75 wt %, for example, about 20 wt % to about 70 wt %, about 20 wt % to about 65 wt %, about 20 wt % to about 60 wt %, about 25 wt % to about 60 wt %, or about 30 wt % to about 60 wt % based on a total weight of the polymer, but is not limited thereto. If the polymer includes the structural unit 1 represented by Chemical Formula 1 within the above ranges, the sensitivity of the photoresist can be further improved or enhanced.

The polymer may have a weight average molecular weight of about 1,000 g/mol to about 300,000 g/mol, for example, about 1,000 g/mol to 200,000 g/mol, for example, 1,000 g/mol to 100,000 g/mol, for example, 2,000 g/mol to 90,000 g/mol, for example, 2,000 g/mol to 70,000 g/mol, for example, 2,000 g/mol to 50,000 g/mol, for example, 5,000 g/mol to 50,000 g/mol, or, for example, 5,000 g/mol to 30,000 g/mol, but is not limited thereto. By having a weight average molecular weight within the above ranges, a carbon content and solubility in the solvent of the resist underlayer composition including the polymer may be adjusted and optimized or enhanced.

The polymer may be included in an amount of about 0.1 wt % to about 50 wt % based on a total weight of the resist underlayer composition. In embodiments, the polymer may be included in an amount of about 0.1 wt % to about 45 wt %, for example, about 0.1 wt % to about 40 wt %, about 0.1 wt % to about 35 wt %, about 0.1 wt % to about 30 wt %, about 0.2 wt % to about 30 wt %, about 0.3 wt % to about 30 wt %, about 0.4 wt % to about 30 wt %, or about 0.5 wt % to about 30 wt % based on a total weight of the resist underlayer composition, but is not limited thereto. By including the polymer within the above ranges in the composition, the thickness, surface roughness, and a degree of planarization of the resist underlayer may be adjusted or enhanced.

The resist underlayer composition according to some example embodiments may include a solvent. The solvent is not particularly limited as long as it has sufficient solubility and/or dispersibility for the polymer according to some example embodiments, but may be, for example, propylene glycol, propylene glycol diacetate, methoxypropanediol, diethylene glycol, diethylene glycol butylether, tri(ethylene glycol)monomethylether, propylene glycol monomethylether, propylene glycol monomethylether acetate (PGMEA), cyclohexanone, ethyllactate, gamma-butyrolactone, N,N-dimethyl formamide, N,N-dimethyl acetamide, methylpyrrolidone, methylpyrrolidinone, methyl 2-hydroxyisobutyrate, acetylacetone, ethyl 3-ethoxypropionate, or a combination thereof.

The resist underlayer composition according to some example embodiments may further include one or more polymers selected from among an acrylic resin, an epoxy resin, a novolac-based resin, a glycoluril-based resin, and a melamine-based resin, in addition to the polymer and solvent, but is not limited thereto.

The resist underlayer composition according to some example embodiments may further include an additive including a surfactant, a thermal acid generator, a photoacid generator, a plasticizer, or a combination thereof.

The surfactant may be used to improve coating defects caused by an increase in a solid content if (e.g., when) forming the resist underlayer, and may be, for example, an alkylbenzenesulfonate salt, an alkylpyridinium salt, polyethylene glycol, a quaternary ammonium salt, or the like, but is not limited thereto.

The thermal acid generator may be an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalene carbonic acid, or/and benzointosylate, 2-nitrobenzyltosylate, and other organic sulfonic acid alkylester may be used, but is not limited thereto.

The plasticizer is not particularly limited, and a variety of suitable plasticizers generally used in the art may be used. Examples of a plasticizer may include low molecular compounds (e.g., low molecular weight compounds) such as phthalic acid esters, adipic acid esters, phosphoric acid esters, trimellitic acid esters, citric acid esters, and/or the like, polyether compounds, polyester-based compounds, polyacetal compounds, and/or the like.

The additive may be included in an amount of about 0.0001 to about 40 parts by weight based on 100 parts by weight of the resist underlayer composition. Within the foregoing ranges, solubility may be improved or enhanced while optical properties of the resist underlayer composition are not (or substantially not) changed.

According to some example embodiments, a resist underlayer manufactured using the aforementioned resist underlayer composition is provided. The resist underlayer may be formed by coating the aforementioned resist underlayer composition on, for example, a substrate and then curing through a heat treatment process.

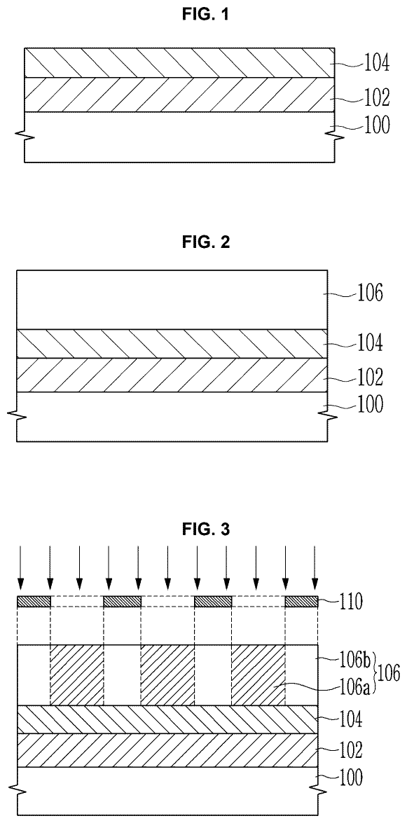

Hereinafter, a method of forming a pattern using the aforementioned resist underlayer composition is described with reference to FIGS. 1-6.

FIGS. 1-6 are cross-sectional views illustrating a method of forming a pattern using the resist underlayer composition according to embodiments of the present disclosure.

Referring to FIG. 1, an etching target is prepared. The etching target may be a thin film 102 formed on a semiconductor substrate 100. Hereinafter, the etching target is limited to the thin film 102. An entire surface of the thin film 102 is pre-washed to remove impurities and/or the like remaining thereon. The thin film 102 may be or include, for example, a silicon nitride layer, a polysilicon layer, and/or a silicon oxide layer.

Subsequently, the aforementioned resist underlayer composition is coated on the surface of the cleaned thin film 102 by utilizing a spin coating method.

Then, the coated composition is dried and baked to form a resist underlayer 104 on the thin film 102. For example, a first baking process may be performed at a temperature about 100° C. to about 500° C., or, for example, about 100° C. to about 300° C. In embodiments, the resist underlayer composition is described above in more detail and thus duplicative description thereof will not be repeated here.

Referring to FIG. 2, a photoresist film 106 is formed by coating a photoresist on the resist underlayer 104.

Examples of the photoresist may be a positive-type photoresist including a naphthoquinonediazide compound and a novolac resin, a chemically-amplified positive photoresist including an acid generator capable of dissociating acid through exposure, a compound decomposed under presence of the acid and having increased dissolubility in an alkali aqueous solution, and an alkali soluble resin, a chemically-amplified positive-type photoresist including an alkali-soluble resin having a group capable of increasing dissolubility in an alkali aqueous solution, and/or the like.

Then, a substrate 100 having the photoresist film 106 is primarily baked. The primary baking may be performed at about 90° C. to about 120° C.

Referring to FIG. 3, the photoresist film 106 may be selectively exposed. Exposure of the photoresist film 106 may be, for example, performed by positioning an exposure mask 110 having a set or predetermined pattern on a mask stage of an exposure apparatus and aligning the exposure mask 110 on the photoresist film 106. Subsequently, light may be irradiated into (e.g., through) the exposure mask such that a set or predetermined region of the photoresist film 106 formed on the substrate 100 may react (e.g., selectively reacts) with light passing (e.g., through) the exposure mask 110 (e.g., by light originally irradiated into (e.g., through) the exposure mask 110).

For example, the light used during the exposure may include electromagnetic radiation selected from among short wavelength light such as an i-line having a wavelength of 365 nanometer (nm), a KrF excimer laser having a wavelength of 248 nm, and/or an ArF excimer laser having a wavelength of 193 nm. In embodiments, EUV (extreme ultraviolet) having a wavelength of 13.5 nm (e.g., corresponding to extreme ultraviolet light) may be used.

The photoresist film of the exposed region 106a has a relatively different hydrophilicity compared with the photoresist film of the unexposed region 106b. Accordingly, the exposed region 106a and non-exposed region 106b of the photoresist film 106 may have different solubility from each other.

Subsequently, the substrate 100 is secondarily baked. The secondary baking may be performed at about 90° C. to about 150° C. By performing the second baking process, the photoresist film in the unexposed region is further cured, thereby preventing the unexposed region from being removed together or swollen (or thereby reducing removal or swelling of the unexposed region) by the developer if (e.g., when) the film in the exposed region is removed by the developer.

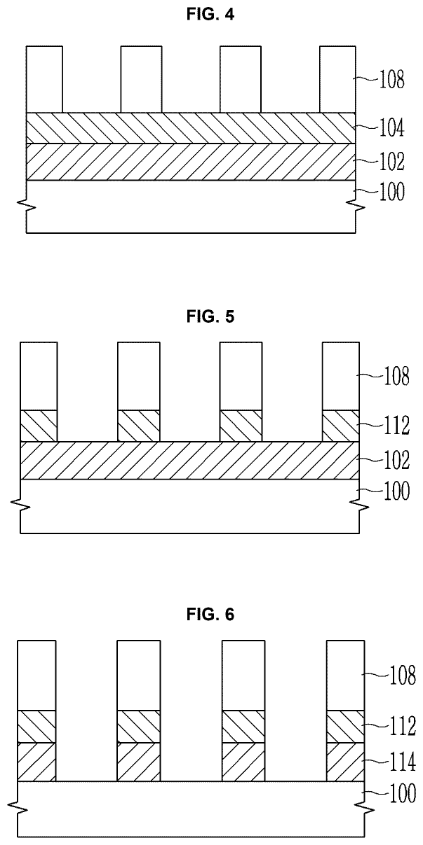

Referring to FIG. 4, for example, the photoresist film 106a of the exposed region is dissolved and then removed using tetra-methyl ammonium hydroxide (TMAH), etc., and thereby the photoresist film 106b remaining after development forms the photoresist pattern 108.

Subsequently, the resist underlayer 104 is etched using the photoresist pattern 108 as an etch mask. An organic film pattern 112 as shown in FIG. 5 is formed through the above etching process. The etching may be, for example, dry etching using etching gas, and the etching gas may be, for example, CHF₃, CF₄, Cl₂, O₂, and/or a mixed gas thereof. As described above, because the resist underlayer formed by the resist underlayer composition according to the embodiment has a fast etch rate, a smooth etching process may be performed within a short time.

Referring to FIG. 6, the photoresist pattern 108 is applied as an etching mask to etch the exposed thin film 102. As a result, the thin film is formed into a thin film pattern 114. In the exposure process performed previously, a thin film pattern 114 formed by an exposure process performed using a short wavelength light source such as an i-line (a wavelength of 365 nm), a KrF excimer laser (a wavelength of 248 nm), and/or an ArF excimer laser (a wavelength of 193 nm) may have a width of tens to hundreds of nm, and the thin film pattern 114 formed by the exposure process performed using the EUV light source may have a width of less than or equal to about 20 nm.

Hereinafter, embodiments of the present disclosure are described in more detail through Examples regarding synthesis of the polymer and preparation of a resist underlayer composition including the same. However, the present disclosure is technically not restricted by the following examples.

### SYNTHESIS EXAMPLES

### Synthesis Example 1

4.9 g of glycidyl methacrylate (Aldrich Corporation), 4.9 g of propyl methacrylate (Aldrich Corporation), 4.8 g of dimethyl 2,2′-azobis(2-methylpropionate) (V-601;TCI), and 64 g of propylene glycol methyl ether acetate (PGMEA) are added to a 500 ml 3-neck round flask to prepare a reaction solution, and a condenser is connected thereto. The reaction solution is heated at 90° C. for 1 hour to proceed with a reaction and then, cooled to room temperature (23° C.). Subsequently, the reaction solution is added dropwise to a beaker including 450 g of heptane, while stirring, to produce a gum, which is then dissolved in 90 g of DMF (dimethyl formamide).

Then, 80.0 g of an intermediate product obtained from the above with 9.0 g of 2-lodopropionic acid, 0.5 g of pyridine, and 0.5 g of butylated hydroxytoluene (BHT) is added to a 500 ml 3-necked round flask to prepare a reaction solution, and a condenser is connected thereto. The reaction solution is heated at 80° C. for 4 hours to proceed with a reaction and then, cooled to room temperature. Then, the reaction solution is added dropwise to a beaker including 450 g of heptane, while stirring, to produce a gum, which is then dissolved in 90.0 g of PGMEA. The corresponding solution is treated with heptane to remove monomolecules (e.g., monomers) and low molecules (e.g., low molecular weight molecules) and then, dried to finally obtain a polymer composed of structural units represented by Chemical Formulas 1-2 and 2-1. (Mw: 8,200 g/mol)

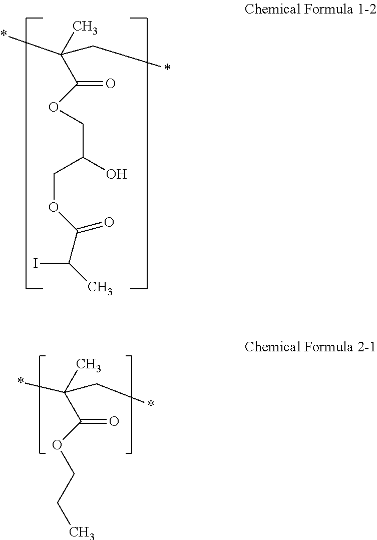

### Synthesis Example 2

41.0 g of cyclohexyl methacrylate and 31.61 g of PGMEA are added to a 500 ml 2-necked round flask under a nitrogen atmosphere and after connecting a condenser thereto, heated to 80° C. Subsequently, a solution prepared by dissolving 20.5 g of glycidyl methacrylate (TCI) and 12.5 g of dimethyl 2,2′-azobis(2-methylpropionate) (V-601) in 82.43 g of PGMEA is added dropwise thereto for 1 hour and then, reacted for 3 hours and cooled to room temperature. Then, the resultant reaction solution is transferred to a 1 L wide-mouth bottle, and 450 g of heptane is added thereto, while stirring, to produce a gum, which is then dissolved in 150 g of tetrahydrofuran (THF). The corresponding solution is treated by using heptane to remove monomolecules (e.g., monomers) and low molecules (e.g., low molecular weight molecules) and then, dried and dissolved in 90 g of DMF.

80.0 g of an intermediate product obtained from the above with 13.0 g of 2,3-diiodobutanoic acid, 0.5 g of pyridine, and 0.5 g of BHT is added to 500 ml 3-necked round flask to prepare a reaction solution, and a condenser is connected thereto. The reaction solution is heated at 80° C. for 4 hours to proceed with a reaction and then, cooled to room temperature. Then, the reaction solution is added dropwise to a beaker including 450 g of heptane, while stirring, to produce a gum, which is then dissolved in 90.0 g of PGMEA. The corresponding solution is treated with heptane to remove monomolecules (e.g., monomers) and low molecules (e.g., low molecular weight molecules) to finally obtain a polymer composed of structural units represented by Chemical Formulas 1-3 and 2-2. (Mw: 11,000 g/mol)

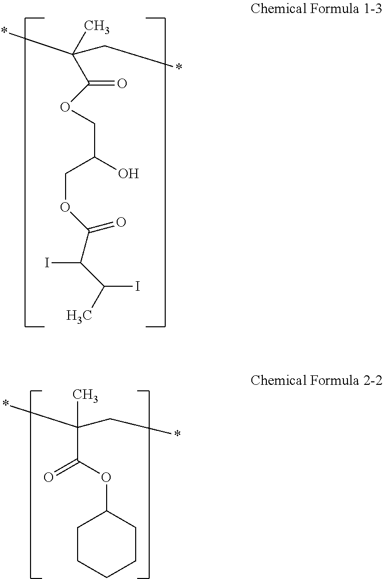

### Synthesis Example 3

30.0 g of methyl methacrylate and 41.61 g of PGMEA are added to a 500 ml 2-necked round flask under a nitrogen atmosphere and after connecting a condenser thereto, heated to 80° C. Subsequently, a solution prepared by dissolving 15.25 g of glycidyl methacrylate (TCI) and 12.5 g of dimethyl 2,2′-azobis(2-methylpropionate) (V-601) in 82.43 g of PGMEA is added thereto for 1 hour and then, reacted for 3 hours and cooled to room temperature. Then, the resultant reaction solution is transferred to a 1 L wide-mouth bottle, and 450 g of heptane is added thereto, while stirring, to generate a gum, which is then dissolved in 150 g of tetrahydrofuran (THF). The corresponding solution is treated with heptane to remove monomolecules (e.g., monomers) and low molecules (e.g., low molecular weight molecules) and then, dried and dissolved in 90.0 g of DMF.

Then, 80.0 g of an intermediate product obtained from the above with 15.0 g of α-lodophenylacetic acid, 0.5 g of pyridine, and 0.5 g of BHT is added to a 500 ml 3-necked round flask to prepare a reaction solution, and a condenser is connected thereto. The reaction solution is heated at 80° C. for 4 hours to proceed with a reaction and then, cooled to room temperature. The reaction solution is added dropwise to a beaker including 450 g of heptane, while stirring, to produce a gum, which is then dissolved in 90.0 g of PGMEA. The corresponding solution is treated with heptane to remove monomolecules (e.g., monomers) and low molecules (e.gg., low molecular weight molecules) and then, dried to finally obtain a polymer composed of structural units represented by Chemical Formulas 1-4 and 2-3. (Mw: 13,000 g/mol)

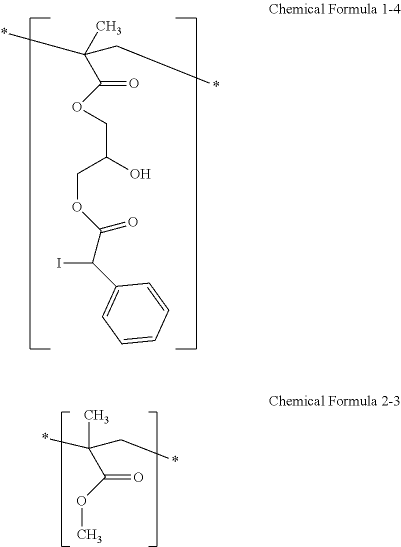

### Synthesis Example 4

10.0 g of 1-adamantaneacetic acid (Aldrich Corp.), 50.0 g of thionyl chloride (Aldrich Corp.), 2.0 g of iodine (Aldrich Corp.) are added to a 250 ml 2-necked round flask to prepare a reaction solution, and a condenser is connected thereto. The reaction solution is heated at 65° C. for 3 hours to proceed with a reaction and then, cooled to room temperature. Subsequently, the reaction solution is added dropwise to a beaker including 200 g of deionized water (DIW), while stirring, and then, DIW is removed therefrom. Then, 200 g of DIW and 200 g of THF are added again to the beaker and then, stirred and dried to obtain a reactant (A).

15.5 g of tert-butyl methacrylate (TCI) and 15.25 g of glycidyl acrylate (TCI), 4.8 g of dimethyl 2,2′-azobis(2-methylpropionate) (V-601; TCI), and 64 g of propylene glycol methyl ether acetate (PGMEA) are added to a 500 ml 3-necked round flask to prepare a reaction solution, and a condenser is connected thereto. The reaction solution is heated at 90° C. for 1 hour to proceed with a reaction and then, cooled to room temperature. Subsequently, the reaction solution is added to a beaker including 450 g of heptane, while stirring, to produce a gum, which is then dissolved in 90 g of DMF. The corresponding solution is treated with heptane to remove monomolecules (e.g., monomers) and low molecules (e.g., low molecular weight molecules), obtaining a polymer (B).

5.0 g of the reactant (A) and 30.0 g of the polymer (B) with 0.3 g of pyridine and 0.3 g of BHT are added to a 250 ml 3-necked round flask to prepare a reaction solution, and a condenser is connected thereto. The reaction solution is heated at 80° C. for 4 hours to proceed with a reaction solution and then, cooled to room temperature. Then, the reaction solution is added dropwise to a beaker including 450g of heptane, while stirring, to produce a gum, which is then dissolved in 90.0 g of PGMEA. The corresponding solution is treated with heptane to remove monomolecules (e.g., monomers) and low molecules (e.g., low molecular weight molecules) to finally obtain a polymer composed of structural units represented by Chemical Formulas 1-5 and 2-4. (Mw: 8,200 g/mol)

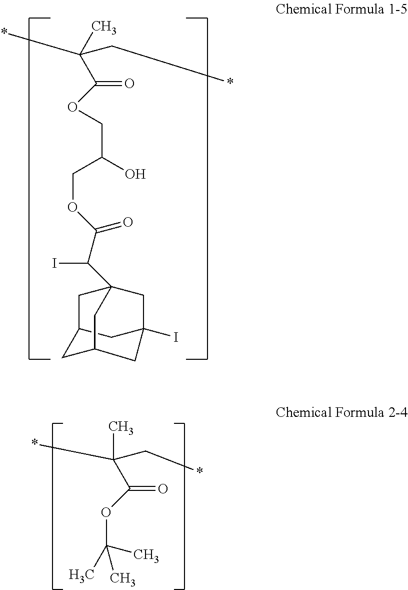

### Comparative Synthesis Example 1

30.0 g of methyl methacrylate and 41.61 g of PGMEA are added to a 500 ml 2-necked round flask under a nitrogen atmosphere and after connecting a condenser thereto, heated to 80° C. Subsequently, a solution prepared by dissolving 15.25 g of glycidyl acrylate (TCI) and 12.5 g of dimethyl 2,2′-azobis(2-methylpropionate) (V-601) in 82.43 g of PGMEA is added dropwise thereto for 1 hour and then, reacted for 3 hours and cooled to room temperature. Then, the resultant reaction solution is transferred to a 1 L wide-mouth bottle, and 450 g of heptane is added thereto, while stirring, to produce a gum, which is then dissolved in 150 g of tetrahydrofuran (THF). The corresponding solution is treated with heptane to remove monomolecules (e.g., monomers) and low molecules (e.g., low molecular weight molecules) and then, dried to finally obtain a copolymer composed of structural units represented by Chemical Formulas 2-3 and 2-4. (Mw=12,000 g/mol)

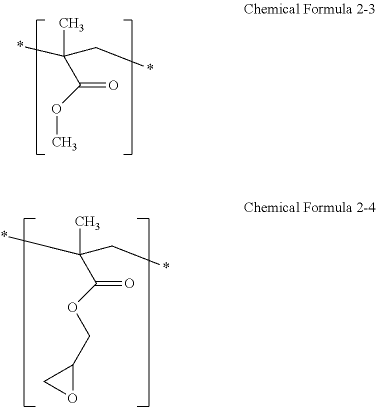

### Comparative Synthesis Example 2

20.0 g of hydroxypropyl methacrylate and 40.0 g of PGMEA are added to a 500 ml 2-necked round flask under a nitrogen atmosphere and after connecting a condenser thereto, heated to 80° C. Subsequently, a solution prepared by dissolving 15.0 g of glycidyl acrylate (TCI) and 10.0 g of dimethyl 2,2′-azobis(2-methylpropionate) (V-601) in 80.0 g of PGMEA is added dropwise thereto for 1 hour and then, reacted for 3 hours and cooled to room temperature. Then, the resultant reaction solution is transferred to a 1 L wide-mouth bottle, and 450 g of heptane is added thereto, while stirring, to produce a gum, which is then dissolved in 150 g of tetrahydrofuran (THF). The corresponding solution is treated with heptane to remove monomolecules (e.g., monomers) and low molecules (e.g., low molecular weight molecules) and then, dried and dissolved in 90.0 g of DMF.

80.0 g of an intermediate product obtained from the above with 15.0 g of 3-iodopropanoic acid, 0.5 g of pyridine, and 0.5 g of BHT is added to a 500 ml 3-necked round flask to prepare a reaction solution, and a condenser is connected thereto. The reaction solution is heated at 80° C. for 4 hours to proceed with a reaction and then, cooled to room temperature. Then, the reaction solution is added dropwise to a beaker including 450 g of heptane, while stirring, to produce a gum, which is then dissolved in 90.0 g of PGMEA. The corresponding solution is treated with heptane to remove monomolecules (e.g., monomers) and low molecules (e.g., low molecular weight molecules) to finally obtain a copolymer composed of structural units represented by Chemical Formulas 3 and 2-5. (Mw=9,800 g/mol)

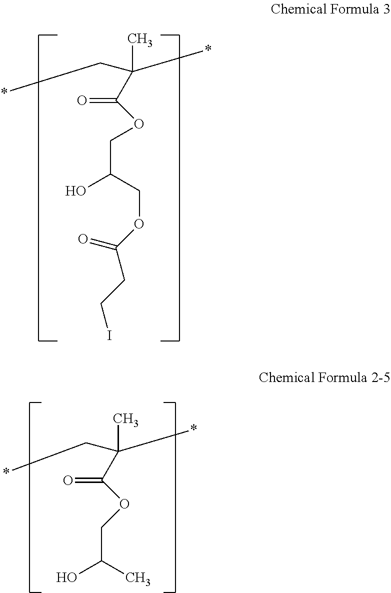

### Comparative Synthesis Example 3

30.0 g of methyl methacrylate and 40.0 g of PGMEA are added to a 500 ml 2-necked round flask under a nitrogen atmosphere and after connecting a condenser thereto, heated to 80° C. Subsequently, a solution prepared by dissolving 15.0 g of glycidyl acrylate (TCI) and 10.0 g of dimethyl 2,2′-azobis(2-methylpropionate) (V-601) in 80.0 g of PGMEA is added dropwise thereto for 1 hour and then, reacted for 3 hours and cooled to room temperature. Then, the reaction solution is transferred to a 1 L wide-mouth bottle, and 450 g of heptane is added thereto, while stirring, to produce a gum, which is then dissolved in 150 g of tetrahydrofuran (THF). The corresponding solution is treated with heptane to remove monomolecules (e.g., monomers) and low molecules (e.g., low molecular weight molecules) and then, dried and dissolved in 90.0 g of DMF.

Subsequently, 80.0 g of an intermediate product obtained from the above with 18.0 g of α,α-difluorophenylacetic acid, 0.5 g of pyridine, and 0.5 g of BHT is added to a 500 ml 3-necked round flask to prepare a reaction solution, and a condenser is connected thereto. The reaction solution is heated at 80° C. for 4 hours to proceed with a reaction and then, cooled to room temperature. Then, the reaction solution is added dropwise to a beaker including 450 g of heptane, while stirring, to produce a gum, which is then dissolved in 90.0 g of PGMEA. The corresponding solution is treated with heptane to remove monomolecules (e.g., monomers) and low molecules (e.g., low molecular weight molecules), finally obtaining a copolymer composed of structural units represented by Chemical Formulas 4 and 2-3. (Mw=13,500 g/mol)

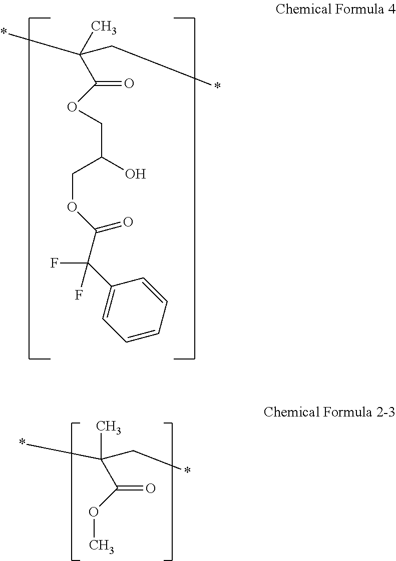

### Preparation of Resist Underlayer Compositions

### Examples and Comparative Examples

Each of the polymers according to the synthesis examples and the comparative synthesis examples, a crosslinking agent (PL1174), and a thermal acid generator (TAG) (pyridinium p-toluenesulfonate, PPTS) were dissolved in PGMEA to a solid concentration of 2 wt %. The obtained solutions were respectively diluted with methyl 2-hydroxyisobutyrate to prepare a resist underlayer composition at a solid concentration of 1 wt % based on a total amount of each composition as shown in Table 1. Each content in Table 1 used wt % based on a total weight of each resist underlayer composition.

TABLE 1

| | Polymer (wt %) | Crosslinking agent | TAG |
|---|---|---|---|
| Example 1 | Synthesis Example 1 (0.84) | 0.15 | 0.01 |
| Example 2 | Synthesis Example 2 (0.84) | 0.15 | 0.01 |
| Example 3 | Synthesis Example 3 (0.84) | 0.15 | 0.01 |
| Example 4 | Synthesis Example 4 (0.84) | 0.15 | 0.01 |
| Comparative | Synthesis Example 5 (0.84) | 0.15 | 0.01 |
| Example 1 | | | |
| Comparative | Synthesis Example 6 (0.84) | 0.15 | 0.01 |
| Example 2 | | | |
| Comparative | Synthesis Example 4 (0.84) | 0.15 | 0.01 |
| Example 3 | | | |

### Evaluation 1: Evaluation of Line Width Roughness (LWR)

The compositions according to Examples 1 to 4 and Comparative Examples 1 to 3 were respectively spin-on coated and heat-treated on a hot plate at 205° C. for 60 seconds to form a 50 Å-thick resist underlayer. Subsequently, on the above underlayer, a photoresist solution was spin-on coated and then, heat-treated on a hot plate at 110° C. for 1 minute to form a photoresist layer. The resist layer was exposed to light by using an e-beam light exposer (an acceleration voltage: 100 keV, Elionix Inc.). Subsequently, the obtained product was heat-treated at 95° C. for 60 seconds, developed with a 2.38 wt % tetramethylammonium hydroxide (TMAH) aqueous solution for 60 seconds, and rinsed with pure water for 15 seconds to form resist patterns.

The formed patterns were examined with respect to line width roughness (LWR) by using a scanning electron microscope (SEM) S-9260 (Hitachi Ltd.), and a 1 distance from a reference line where an edge should be for an edge range of 2 um was measured in a length direction of the patterns.

Each measured exposure dose and LWR according to the examples and the comparative examples were converted into a ratio to the exposure dose or LWR according to Comparative Example 1 as Ref., and the results are shown in Table 2, wherein the smaller exposure dose and line width roughness (LWR), the better pattern formation ability and sensitivity.

$$* Exposure dose ( or LWR ) ( \% ) = ( Exposure dose ( or LWR ) according to each Experimental Example - Exposure dose ( or LWR ) according to Comparative Example 1 ) / Exposure dose ( or LWR ) accorrding to Comparative Example 1 \times 100$$

TABLE 2

| | Exposure dose | LWR |
|---|---|---|
| Example 1 | 93% | 95% |
| Example 2 | 90% | 96% |
| Example 3 | 94% | 95% |
| Example 4 | 91% | 95% |
| Comparative Example 1 | 100% | 100% |
| Comparative Example 2 | 95% | 98% |
| Comparative Example 3 | 99% | 100% |

Referring to Table 2, the photoresist films of the examples were confirmed to be cured by a smaller exposure dose than the photoresist films of the comparative examples, and in addition, the photoresist films of the examples exhibited excellent sensitivity, compared with those of the comparative examples. In addition, the photoresist films of the examples had smaller LWR and thus more uniform patterns than those of the comparative examples.

As a result, the compositions of the examples including a polymer having a structural unit in which iodine was substituted on a carbon atom to which a terminal functional group was boned were confirmed to form a photoresist film having excellent sensitivity and uniform patterns, compared with the compositions of Comparative Examples 1 to 3.

### Evaluation 2: Evaluation of Storage Stability

The resist underlayer compositions of the examples and the comparative examples were stored at 35° C. for 1 month, and then, whether or not precipitates were formed after stored for 1 month was examined with naked eyes (e.g., unassisted eyes) to evaluate storage stability. If the precipitates were not formed, the storage stability was evaluated to be excellent, and the results are shown in Table 3.

TABLE 3

| | Precipitates |
|---|---|
| Example 1 | not generated |
| Example 2 | not generated |
| Example 3 | not generated |
| Example 4 | not generated |
| Comparative Example 1 | not generated |
| Comparative Example 2 | generated |
| Comparative Example 3 | generated |

Referring to Table 3, the resist underlayer compositions of the examples exhibited no precipitate formation even after being stored for 1 month, but the resist underlayer compositions of Comparative Examples 2 and 3 exhibited the precipitate formation after being stored for 1 month. Accordingly, the compositions of the examples exhibited excellent storage stability.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6.

Applicant therefore reserves the right to amend this specification, including the claims, to expressly recite any sub-range subsumed within the ranges expressly recited herein.

Hereinbefore, certain embodiments of the present disclosure have been described and illustrated, however, it should be apparent to a person having ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims, and equivalents thereof, of the present disclosure.

Description of Symbols

| | |
|---|---|
| 100: substrate | 102: thin film |
| 104: resist underlayer | 106: photoresist film |
| 106a: exposed region | 106b: unexposed region |
| 108: photoresist pattern | 110: mask |
| 112: organic film pattern | 114: thin film pattern |

What is claimed is:

1. A resist underlayer composition, comprising:
a polymer comprising a structural unit represented by Chemical Formula 1, and a solvent: 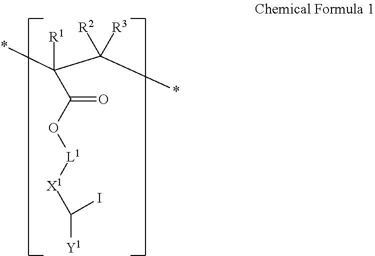
wherein, in Chemical Formula 1,
R¹ to R³ are each independently hydrogen, deuterium, or a substituted or unsubstituted C1 to C10 alkyl group,
L¹ is a single bond, a substituted or unsubstituted C1 to C10 alkylene group, a substituted or unsubstituted C2 to C10 alkenylene group, a substituted or unsubstituted C2 to C10 alkynylene group, a substituted or unsubstituted C1 to C10 heteroalkylene group, a substituted or unsubstituted C2 to C10 heteroalkenylene group, or a combination thereof,
X¹ is a single bond, —O—, —C(═O)—, —(CO)O—, —O(CO)O—, —NR^{a}— (wherein, R^{a} is hydrogen, deuterium, or a substituted or unsubstituted C1 to C10 alkyl group), or a combination thereof,
Y¹ is *—(CH₂)n-(CHI)m-CR^{x}R^{y}R^{z} (wherein, n is one of the integers from 0 to 5, m is 0 or 1, and R^{x} to R^{z} are each independently hydrogen, deuterium, or a halogen atom), a substituted or unsubstituted C3 to C20 cycloalkyl group, two or more fused rings of substituted or unsubstituted C3 to C10 cycloalkyl groups, a substituted or unsubstituted C2 to C20 heterocycloalkyl group, a substituted or unsubstituted C6 to C20 aryl group, or a substituted or unsubstituted C2 to C20 heteroaryl group, and
* is a linking point.

2. The resist underlayer composition as claimed in claim 1, wherein in Chemical Formula 1, L¹ is a substituted or unsubstituted C1 to C10 alkylene group, and X¹ is —(CO)O—.

3. The resist underlayer composition as claimed in claim 1, wherein the polymer comprises a structural unit represented by Chemical Formula 1-1: 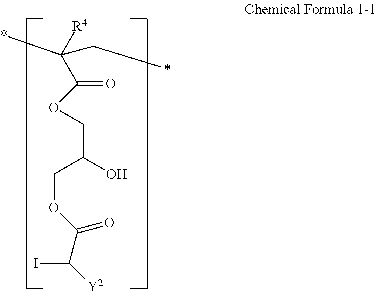
wherein, in Chemical Formula 1-1,
R⁴ is hydrogen, deuterium, or a substituted or unsubstituted C1 to C10 alkyl group,
Y² is a substituted or unsubstituted methyl group, —CHICH₃, a substituted or unsubstituted C3 to C20 cycloalkyl group, two or more fused rings of substituted or unsubstituted C3 to C10 cycloalkyl groups, or a substituted or unsubstituted C6 to C10 aryl group, and
* is a linking point.

4. The resist underlayer composition as claimed in claim 1, wherein the polymer further comprises a structural unit represented by Chemical Formula 2: 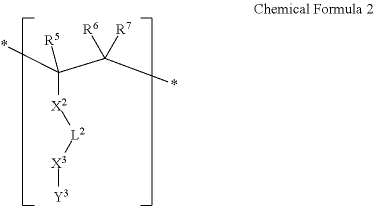
wherein, in Chemical Formula 2,
R⁵ to R⁷ are each independently hydrogen, deuterium, or a substituted or unsubstituted C1 to C10 alkyl group,
X² and X³ are each independently a single bond, —O—, —S—, —S(═O)—, —S(═O)₂—, —C(═O)—, —(CO)O—, —O(CO)O—, —NR^{b}— (wherein, R^{b} is hydrogen, deuterium, or a C1 to C10 alkyl group), or a combination thereof,
L² is a single bond, a substituted or unsubstituted C1 to C10 alkylene group, a substituted or unsubstituted C1 to C10 heteroalkylene group, a substituted or unsubstituted C3 to C20 cycloalkylene group, a substituted or unsubstituted C2 to C20 heterocycloalkylene group, a substituted or unsubstituted C6 to C20 arylene group, a substituted or unsubstituted C2 to C20 heteroarylene group, or a combination thereof,
Y³ is hydrogen, deuterium, a hydroxy group, a nitro group, a cyano group, amine group,-COOH, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C2 to C10 heteroalkenyl group, a substituted or unsubstituted C2 to C10 heteroalkynyl group, a substituted or unsubstituted C3 to C20 cycloalkyl group, a substituted or unsubstituted C2 to C20 heterocycloalkyl group, a substituted or unsubstituted C6 to C20 aryl group, or a substituted or unsubstituted C2 to C20 heteroaryl group, and
* is a linking point.

5. The resist underlayer composition as claimed in claim 4, wherein in Chemical Formula 2, X² is —(CO)O—, X³ is a single bond, and Y³ is a substituted or unsubstituted C1 to C10 alkyl group, a substituted or unsubstituted C3 to C20 cycloalkyl group, or a substituted or unsubstituted C6 to C20 aryl group.

6. The resist underlayer composition as claimed in claim 1, wherein the polymer comprises any one or more selected from among the structural units represented by Chemical Formula 1-2 to Chemical Formula 1-5:

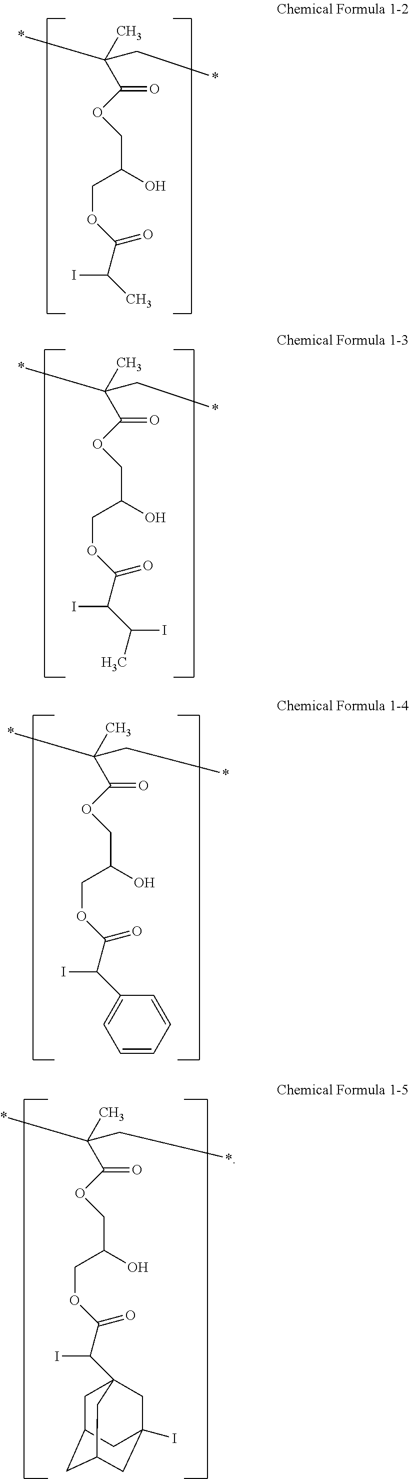

7. The resist underlayer composition as claimed in claim 1, wherein the structural unit represented by Chemical Formula 1 is included in an amount of about 20 wt % to about 80 wt % based on a total weight of the polymer.

8. The resist underlayer composition as claimed in claim 1, wherein a weight average molecular weight of the polymer is about 1,000 g/mol to about 300,000 g/mol.

9. The resist underlayer composition as claimed in claim 1, wherein the polymer is included in an amount of about 0.1 wt % to about 50 wt % based on a total weight of the resist underlayer composition.

10. The resist underlayer composition as claimed in claim 1, wherein the composition further comprises one or more polymers selected from among an acrylic resin, an epoxy resin, a novolac-based resin, a glycoluril-based resin, and a melamine-based resin.

11. The resist underlayer composition as claimed in claim 1, wherein the composition further comprises an additive of a surfactant, a thermal acid generator, a photoacid generator, a plasticizer, or a combination thereof.

12. A method of forming a pattern, the method comprising
forming an etching target layer on a substrate,
forming a resist underlayer by applying the resist underlayer composition as claimed in claim 1 on the etching target layer,
forming a photoresist pattern on the resist underlayer, and
sequentially etching the resist underlayer and the etching target layer using the photoresist pattern as an etching mask.
